(19) United States
(12) Patent Application Publication
(10) Pub. No.: US 2012/0303306 A1
(43) Pub. Date: Nov. 29, 2012

(54) METHOD OF SUBSYNCHRONOUS RESONANCE DETECTION

(76) Inventors: Maciej Orman, Radziszow (PL); Przemyslaw Balcerek, Krakow (PL); Michal Orkisz, Krakow (PL)

(21) Appl. No.: 13/518,920

(22) PCT Filed: Feb. 4, 2011
(86) PCT No.: PCT/EP2011/000553

§ 371 Date: Jun. 25, 2012

(30) Foreign Application Priority Data
Feb. 17, 2010 (EP) 10460004.4

(51) Int. Cl. G01R 19/02; G06F 19/00

(52) U.S. Cl. 702/65

(57) ABSTRACT

The subject of the invention is a method of subsynchronous resonance detection in electrical power systems with series capacitors. Voltage signals are measured on line and by using finding zero crossing points of discrete signal of measured voltage, positive and negative half cycles of the wave form of discrete signal of voltage are calculated in a computer device to which constant parameters are delivered by the user. The inventive method comprises the following actions:
creating a demodulated signal (U_{Dem}) of voltage by adding the minimum value of negative half cycle of the wave form of discrete processed signal (U_{X}) of voltage to the maximum value of positive half cycle of the wave form of discrete processed signal of voltage (U_{X}) for time intervals having a signal length (T_{L}), where (T_{L}) is a constant parameter, delivered by the user,
calculating a root mean square value (RMS) for demodulated signal of voltage U_{Dem} and comparing it with the value of another constant parameter delivered by the user as the level of root mean square value (RMS_{Lev}) and when the value of (RMS) is smaller than the value of (RMS_{Lev}) it indicates that there is no subsynchronous resonance, and when the value of RMS is bigger than the value of (RMS_{Lev}), the presence of subsynchronous resonance is identified by the determination of voltage amplitude (A_{Fss}) of subsynchronous resonance and/or frequency (f_{Fss}) of subsynchronous resonance.

The subject of the invention is a method of subsynchronous resonance detection in electrical power systems with series capacitors.

In general, the subsynchronous resonance phenomenon SSR (SubSynchronous Resonance) occurs in electrical power systems as a result of the interaction of a turbine-generator with a long-distance series compensated transmission line. There is a condition of an electrical power system where electrical networks exchange energy with the mechanical system of the generator at frequencies less than the nominal frequency of the transmission line (50 or 60 Hz).

Subsynchronous resonance is addressed in three categories, the induction generator effect, torsional interaction and torque amplification. The first two types are caused by a steady state disturbance, while the third is excited by transient disturbances.

Series capacitors enhance the capabilities of power electrical systems by compensating transmission line inductance thus increasing the capacity of lines and thereby improving steady state and transient stability limits. However, the use of series capacitors increase the risk of occurrence of the subsynchronous resonance phenomenon. Typically, the frequency of subsynchronous resonance has a value in the range 15%-90% of the nominal frequency of the transmission line.

The known methods of detecting subsynchronous resonance SSR are based on filtering techniques or an analysis of generator shaft vibration. Another method is known from U.S. Pat. No. 4,607,217. Subsynchronous resonance is detected in an AC electrical power supply system by determining changes in the length of successive wave-form half cycles which are the basis for identifying subsynchronous resonance. The parameter change measured is the wave period, and changes in the ratio of the difference of the period of positive and period of negative half cycles over the sum of the period positive and the period of negative half cycles are related to the detection of subsynchronous resonance. The invention is based on the observation that subsynchronous frequency in the current line creates a longer half cycle and shorter half cycles. The difference between the half cycle periods is measured successively to provide a method of detecting the presence of subsynchronous resonance.

A disadvantage of this method is the presence of a time delay between the appearance of the subsynchronous resonance phenomenon and its detection. This time delay may be too long for SSR frequency detection, which may result in damage to the shaft or maloperation of the transmission line protection relay. This disadvantage is overcome by the invented method which allows SSR detection and identification faster in comparison to known techniques and requires the use of small sample amount of input data than in known solutions.

The essence of the inventive method of subsynchronous resonance detection in electrical power systems with series capacitors, in which voltage signals are measured on line and by using a method of finding zero crossing points of discrete signal of measured voltage, positive and negative half cycles of a wave form of discrete signal of voltage are calculated in a computer device to which constant parameters are delivered by the user, is that it includes the following actions:
creating a demodulated signal of voltage U_{Dem} by adding minimum value of negative half cycle of the wave form of discrete processed signal of voltage U_{X} to maximum value of positive half cycle of the wave form of discrete processed signal of voltage U_{X} for time intervals having a signal length T_{L}, where T_{L} is a constant parameter, delivered by the user,
calculating a root mean square value RMS for demodulated signal of voltage U_{Dem} and comparing it with the value of another constant parameter delivered by the user as the level of root mean square value RMS_{Lev} and when the value of (RMS) is smaller than the value of RMS_{Lev} it indicates that there is no subsynchronous resonance, and when the value of RMS is bigger than the value of RMS_{Lev}, the presence of subsynchronous resonance is identified by the determination of voltage amplitude A_{Fss} of subsynchronous resonance and/or frequency f_{Fss} of subsynchronous resonance.

Preferably during finding zero crossing, two hystereses for positive and negative half cycles of the wave form are established for the determination of sequences of consecutive time intervals T_{Poz1}, T_{Neg1}, . . . T_{PozN}, T_{NegN}, respectively for positive U_{Poz} and negative U_{Neg} part of discrete processed signal U_{X} between zero crossings in order to create the upper envelope Eᵤₚ and the lower envelope E_{low} of discrete processed signal U_{X}.

Preferably the absolute value of hysteresis for positive and negative half cycles of the wave form is equal to the root mean square value level RMS_{Lev}.

Preferably the voltage signal length T_{L} has a time value in the time domain of minimum 0.2 s.

A computer program for detection of subsynchronous resonance in electrical power systems with series capacitors, which computer program is loadable in and executable on a data processing unit of a computer device (8), and which computer program when being executed by the data processing unit of the computer performs the method according to claims 1-4.

The method according to the present invention is explained on the basis of an embodiment presented in the drawing, where:

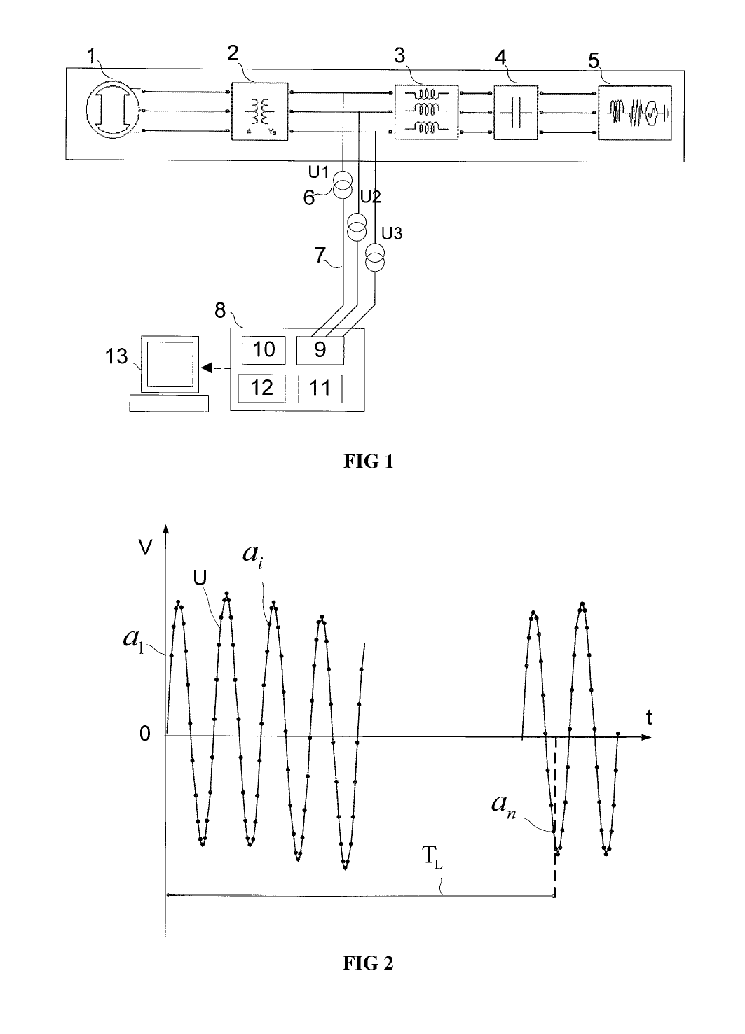

FIG. 1—shows schematically an electrical power system with series capacitors and with a generator,

FIG. 2—shows a waveform of power system voltage with subsynchronous resonance frequency before a demodulation,

FIG. 3—shows a waveform of discrete processed signal,

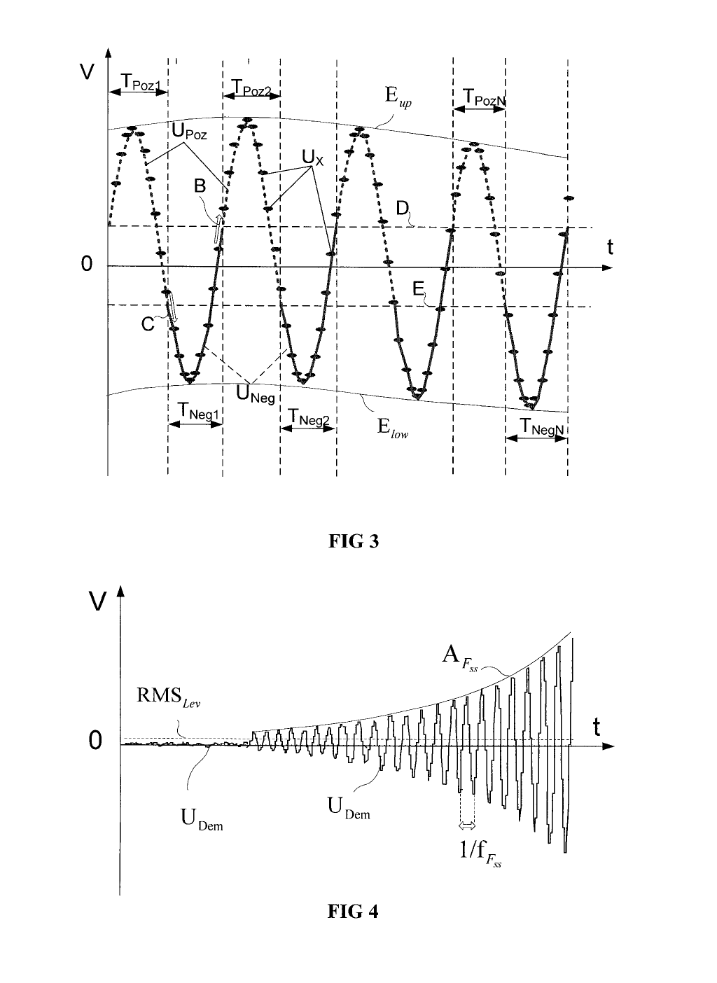

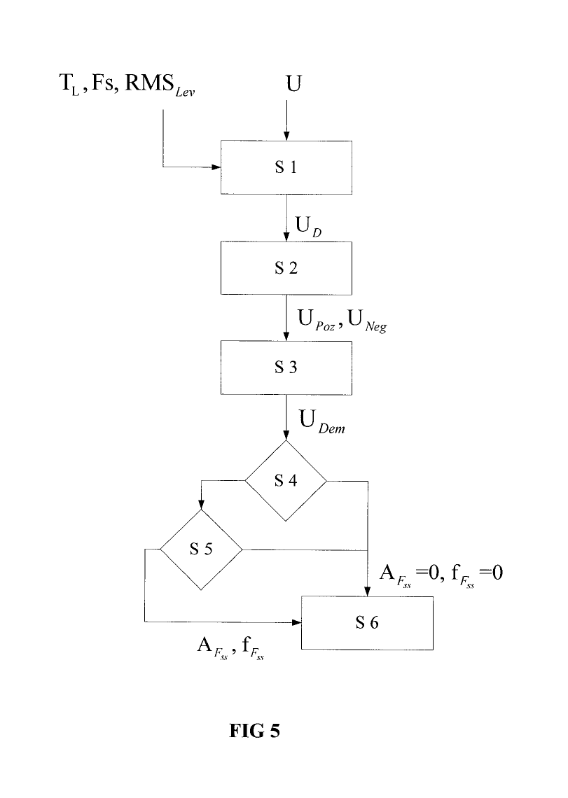

FIG. 4—shows a waveform of demodulated signal with subsynchronous resonance frequency,

FIG. 5—shows a flowchart of operations performed while detecting subsynchronous resonance according to the invention.

The electrical power system for the implementation of the inventive method is presented in FIG. 1. The electrical power system comprises a turbine-generator 1, which forms a mechanical part of the system, and three-phase AC transmission lines connected to the turbine-generator, which together with an HV transformer 2, the impedances 3 of the lines, series capacitors 4, and end consumers 5 of the power systems form an electrical part of the power system. To each phase of the three-phase transmission lines, between the transformer 2 and the series capacitors 4, a capacitor voltage transformer CVT 6 is connected for measuring the voltage of lines U1, U2, U3. Each of the CVT transformers 6 is connected through a communication link 7 with a device for detecting and identify subsynchronous resonance phenomenon 8 in the electrical part of the power system. The device 8 is a computer with a processor unit for implementation of the method of detecting SSR and it may be a part of a protective relay or it may be a computer device installed separately to the system. The device 8 includes an analogue-digital converter 9 for converting the measured analogue signal into a digital signal, a subsynchronous resonance-detecting unit 10 for detecting SSR in transmission lines, a calculation unit 11 and a storage unit 12 for calculating and gathering data processed during the operation, and external peripheral devices 13 for visualising the results of SSR detection. The analogue-digital converter 9 for converting the measured analogue signal into a digital signal may be installed in a CVT transformer 6 instead in the device 8, which is not shown in the drawing.

The method according to the invention is realized as depicted in FIG. 5 in the following steps.

### Step S1

Determination of Discrete Signal U_{D} from Measured Online Signal U.
The voltage signal U1, U2, U3 of transmission line is measured by the CVT transformer 6 and converted into a discrete signal U_{D} in the analogue-digital converter 9. The discrete signal U_{D} consists of voltage value aᵢ of i consecutive samples. For the conversion process, some constant parameters are delivered to the analogue-digital converter 9, and the conversion process is well known in the art.
The first constant parameter delivered to the analogue-digital converter 9 is the sampling frequency Fs. This parameter defines the number of samples per second taken from the analogue signal U (signal U is presented in FIG. 2 as the wave form). Usually the sampling frequency is set as 1 kHz minimum, which is also a default setting for the presented invention. Settings of a lower sampling frequency may result in incorrect calculation.
The second constant parameter delivered to the analogue-digital converter 9 is the signal length T_{L}. This parameter presented in FIG. 2 defines the length of an analogue voltage signal U taken for analogue-digital conversion. To produce reliable results of future next steps the value of signal length T_{L} should be equal to one period of the lowest subsynchronous frequency which can appear in the electrical power system. In the embodiment of the invention the value was set as minimum T_{L}=0.2 [s], which corresponds to 5 Hz of subsynchronous frequency of a transmission line. Settings of shorter signal length T_{L} may result in incorrect calculation.
The third constant parameter delivered to the analogue-digital converter 9 is a root mean square value RMS_{Lev} which defines the statistical magnitude of the discrete signal U_{D}. The RMS_{Lev} value should be equal to the amplitude of the noise level of the CVT transformer 6, which is known for each specific CVT. In future next steps this parameters allows to distinguished noise from the discrete signal U_{D}.

### Step S2

Calculation of Discrete Processed Signal U_{X} and Determination of Zero Crossing Points in Order to Calculate Sequences T_{Poz1}, T_{Neg1}, . . . T_{PozN}, T_{NegN}, of Time Intervals Respective for Positive U_{Poz} and Negative U_{Neg} Part of Discrete Processed Signal U_{X} Between Zero Crossings Points.

First an arithmetic mean value Xₘₑₐₙ of discrete signal U_{D} for signal length T_{L}—FIG. 2 is calculated as follows:

$${X}_{mean} = \frac{{a}_{1} + {a}_{2} + … {a}_{i} … + {a}_{n}}{n} \qquad ( 1 )$$

where aᵢ is the voltage value of sample i and n is the number of all samples in the discrete signal U_{D}. The number of samples n is equal to the sampling frequency Fs multiplied by signal length T_{L}.

Then discrete processed signal U_{X} is calculated by subtracting mean value Xₘₑₐₙ from the voltage value aᵢ of every sample point of the discrete signal U_{D}. If there is no subsynchronous resonance, the discrete processed signal U_{X} maps the dominant nominal frequency of the transmission line. If there is subsynchronous occurrence, the discrete processed signal U_{X} consists of the nominal frequency of the transmission line and subsynchronous frequency components.

U_{X}=aᵢ−Xₘₑₐₙₛ (2)

for i=1 . . . n .

Then the zero crossings points are identified by detecting changes in the discrete processed signal U_{X} sign (+) or (−)—FIG. 3. Always there are two types of zero crossings. One of them is when the signal value is increasing—positive zero crossing, the other when the signal value is decreasing—negative zero crossing. The positive zero crossing (arrow B) is detected when a discrete processed signal U_{X} changes its value from minus to plus and when its value is bigger than the positive hysteresis value established as the value of the root mean square value RMS_{Lev} which is known for each specific CVT 6, marked in FIG. 3 as D. The negative zero crossing (arrow C) is detected when a discrete processed signal U_{X} changes its value from plus to minus and when its value is smaller than the negative hysteresis value established as a minus value of the root mean square value RMS_{Lev} which is known for each specific CVT 6, marked in FIG. 3 as E. The hystereses D and E are established in order to avoid mixing zero crossing with noise which always appears in signals collected from real electrical power systems.

After finding the first zero crossing point, which can be positive or negative, the next zero crossing point, which is negative or positive respectively, is found, the time interval T_{Poz1} or T_{Neg1} between this zero crossing points is determined as an interval for calculating the positive part U_{Poz} (marked in FIG. 3 as dashed line) or the negative part U_{Neg} (marked in FIG. 3 as continuous line) relative to the discrete processed signal U_{X}. Sequences of consecutive time intervals T_{Poz1}, T_{Neg1}, . . . T_{PozN}, T_{NegN}, respectively for the positive U_{Poz} the negative U_{Neg} part of discrete processed signal U_{X} between zero crossings are the result of this step.

### Step S3

### Calculation of a Demodulated Signal U_{Dem}.

First for each T_{Poz1}, . . . , T_{PozN}, of time intervals respectively for positive U_{Poz} from the signal length equal to the value of T_{L}, the maximum values of the discrete processed signal U_{X} are calculated and then from the values of such maxima the upper envelope Eᵤₚ of the discrete processed signal U_{X} is created.

Similarly for each T_{Neg1}, . . . , T_{NegN} of time intervals respectively for negative U_{Neg} from the signal length equal to the value of T_{L}, the minimum values of the discrete processed signal U_{X} are calculated and then from the values of such minima the lower envelope E_{low} of discrete processed signal U_{X} is created.

Next the demodulated signal U_{Dem} is calculated by adding the values of the lower envelop E_{low} to the values of the upper envelop Eᵤₚ

U_{Dem}=EᵤₚE_{low} (3)

Contrary to the discrete processed signal U_{X}, the demodulated signal U_{Dem} does not contain the nominal frequency of the transmission line.

If the subsynchronous resonance phenomenon occurs, the discrete demodulation signal U_{Dem} contains a subharmonic resonance frequency which appears as the dominant one. Before the appearance of the subsynchronous resonance phenomenon, the demodulated signal U_{Dem} is smaller than the RMS_{Lev} value. At the moment when the subsynchronous resonance appears, the demodulated signal U_{Dem} exceeds the RMS_{Lev} value.

### Step S4

### Detection of the Presence of Subsynchronous Resonance Frequency in Demodulated Signal U_{Dem}

by comparing the root mean square RMS value of the demodulated signal U_{Dem} with the value of RMS_{LeV}

First the root mean square RMS value of the demodulated signal U_{Dem} is performed. RMS value is the statistic magnitude of the discrete signal, the details of such calculation are well known to those skilled in the art.

Then the RMS value is compared to the RMS_{Lev} value which was delivered as a parameter in the first step.

If the RMS value of U_{Dem} is smaller than the RMS_{Lev} value, that means that there is no subsynchronous resonance frequency detected in demodulated signal U_{Dem}

In this case an amplitude of subsynchronous resonance frequency A_{F}_{ₛₛ} and the respective frequency f_{F}_{ₛₛ} are considered equal to zero.

If the RMS value of U_{Dem} signal is bigger than or equal to the RMS_{Lev} value, further analysis is performed in step S5.

### Step S5

Calculation and Identification of Voltage Amplitude A_{F}_{ₛₛ} and Frequency f_{F}_{ₛₛ}, Related to Subsynchronous Resonance

First the calculation of FFT (Fast Fourier Transform) of U_{Dem} signal is performed. The FFT operation transforms the signal from the time domain into signal in the frequency domain; the details of such calculation are well known to those skilled in the art.

Then the highest value of a voltage amplitude A_{F}_{ₛₛ} in a spectrum band between 10% and 90% of the nominal frequency of the transmission line is calculated and compared to the RMS_{Lev} value.

If the highest value of a voltage amplitude A_{F}_{ₛₛ} is smaller then the value of RMS_{Lev}, that means that there is no subsynchronous resonance frequency detected (A_{F}_{ₛₛ}=0, f_{F}_{ₛₛ}=0).

If the highest value of a voltage amplitude A_{F}_{ₛₛ} bigger than or equal to the value of RMS_{Lev} then the value of amplitude A_{F}_{ₛₛ} and the respective frequency f_{F}_{ₛₛ} are considered subsynchronous resonance.

### Step 6

Visualization of Subsynchronous Resonance Amplitude as the Highest Value of a Voltage Amplitude A_{F}_{ₛₛ} and/or the Respective Frequency f_{F}_{ₛₛ}.

In this step the subsynchronous resonance amplitude is displayed as the highest value of a voltage amplitude A_{F}_{ₛₛ} and/or the respective resonance frequency is also displayed, using well known means for displaying or printing data, connected to the computer device (8), which is not presented in the drawings.

1. A method of subsynchronous resonance detection in power electrical systems with series capacitors in which voltage signals are measured on line and by finding zero crossing points of the discrete signal of the measured voltage, positive and negative half cycles of the wave form of the discrete signal of voltage are calculated in a computer device to which constant parameters are delivered by the user, comprising the following actions:
creating a demodulated signal (U_{Dem}) of voltage by adding the minimum value of the negative half cycle of the wave form of discrete processed signal (U_{X}) of voltage to the maximum value of the positive half cycle of the wave form of discrete processed signal (U_{X}) for time intervals having a signal length (T_{L}), where (T_{L}) is a constant parameter, delivered by the user,
calculating a root mean square value (RMS) for demodulated signal of voltage (U_{Dem}) and comparing it with the value of another constant parameter delivered by the user as the level of root mean square value (RMS_{Lev}) and when the value of (RMS) is smaller than the value of (RMS_{Lev}) it indicates that there is no subsynchronous resonance, and when the value of (RMS) is bigger than the value of (RMS_{Lev}), the presence of subsynchronous resonance is identified by the determination of voltage amplitude (A_{Fss}) of subsynchronous resonance and/or frequency (f_{Fss}) of subsynchronous resonance.

2. A method according to claim 1, characterised in that during finding zero crossing points, two hystereses for positive and negative half cycles of the wave form are established for determination of sequences of consecutive time intervals (T_{Poz1}, T_{Neg1}, . . . T_{PozN}, T_{NegN},) respectively for the positive (U_{Poz}) and negative (U_{Neg}) part of discrete processed signal (U_{X}) between zero crossings points in order to create the upper envelope (Eᵤₚ) and the lower envelope (E_{low}) of discrete processed signal (U_{X}).

3. A method according to claim 2, characterised in that an absolute value of hysteresis for positive and negative half cycles of the wave form is equal to the root mean square value level (RMS_{Lev}).

4. A method according to claim 1, characterised in that the signal length (T_{L}) has a time value in the time domain of minimum 0.2 s.

5. A computer program for detection of subsynchronous resonance in electrical power systems with series capacitors, which computer program is loadable in and executable on a data processing unit of a computer device and which computer program when being executed by the data processing unit of the computer performs the method according to claim 1.
